(19) United States
(12) Patent Application Publication
(10) Pub. No.: US 2026/0040643 A1
(43) Pub. Date: Feb. 5, 2026

(54) MULTILAYER ANNEALED SILICIDE

(71) Applicant: Texas Instruments Incorporated, Dallas, TX (US)

(72) Inventor: Daniel Dwyer, Lehi, UT (US)

(21) Appl. No.: 18/789,825

(22) Filed: Jul. 31, 2024

(51) Int. Cl. H01L 21/285

(52) U.S. Cl. CPC H01L 21/28518

(57) ABSTRACT

In one example, a method of forming an integrated circuit includes receiving a partially formed semiconductor device over a substrate. The semiconductor device includes a semiconductor layer. A NiₓPt_{y} layer is formed on the semiconductor layer. A NiₘPtₙ layer is formed on the NiₓPt_{y} layer. The NiₓPt_{y} layer and the NiₘPtₙ layer are heated, thereby forming a nickel silicide layer extending into the semiconductor layer. A remaining portion of the NiₘPtₙ layer is removed.

### RELATED APPLICATION

The present application is related to U.S. application Ser. Nos. 18/520,527, 18/608,669, 18/680,460, 18/679,642, and 18/731,016 each of which is incorporated by reference herein in its entirety.

### BACKGROUND

While certain metals can have low electrical resistance, there can be high electrical resistance or non-ohmic conduction at interfaces where metal and semiconductor layers contact each other. Higher electrical resistance at certain interfaces between dissimilar layers can degrade performance and reliability of certain electronic circuitry, such as a transistor. The diffusion of nickel into a semiconductor layer (e.g., to form nickel silicide) can lower the contact resistance and/or non-ohmic conduction between interposing dissimilar layers. However, the diffusion of nickel can result in nickel spike-like defects that form during subsequent high-temperature processing, and such defects can themselves cause certain reliability and performance issues. The diffusion of metal into a semiconductor layer can also be subject to an overburden of the diffusing metal, such that the undiffused metal may need to be stripped away to facilitate subsequent processing. The complete stripping of certain undiffused metal can itself be problematic.

### SUMMARY

In one example, a method of forming an integrated circuit includes receiving a partially formed semiconductor device over a substrate. The semiconductor device includes a semiconductor layer. A NiₓPt_{y} layer is formed on the semiconductor layer. A NiₘPtₙ layer is formed on the NiₓPt_{y} layer, with y being greater than n. The NiₓPt_{y} layer and the NiₘPtₙ layer are heated, thereby forming a nickel silicide layer extending into the semiconductor layer. A remaining portion of the NiₘPtₙ layer is removed.

In another example, a method of forming an integrated circuit includes forming a NiₓPt_{y} layer on a semiconductor layer over a substrate. A NiₘPtₙ layer is formed on the NiₓPt_{y} layer, with y being greater than n. A NiₚPt_{q} layer is formed on the NiₘPtₙ layer, with n greater than q. The NiₓPt_{y} layer, the NiₘPtₙ layer, and the NiₚPt_{q} layer are heated, thereby forming a silicide layer, including nickel, silicon and platinum, on the semiconductor layer. Remaining portions of the NiₘPtₙ layer and the NiₚPt_{q} are removed.

In another example, a method of forming an integrated circuit includes receiving a partially formed semiconductor device over a substrate. The semiconductor device includes a semiconductor layer. A NiₓPt_{y} layer is formed on the semiconductor layer. A NiₘPtₙ layer is formed on the NiₓPt_{y} layer, y being less than n. A nickel platinum silicide layer is formed by reacting the NiₓPt_{y} layer and the NiₘPtₙ layer with the semiconductor layer.

### BRIEF DESCRIPTION OF THE DRAWINGS

FIGS. 1 through 6 are respective cross-sectional views of a portion of a semiconductor device at intermediate stages of manufacturing according to some examples.

FIG. 7 is a cross-sectional view of a portion of a semiconductor device at an intermediate stage of manufacturing according to some examples.

FIGS. 8 through 13 are respective cross-sectional views showing a partially-formed semiconductor device including a transistor region, in which are shown intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor devices and their fabrication, including processing that enhances electrical conductivity at a contact surface of nickel silicide films. Nickel silicide is a compound often used in semiconductor device fabrication as a contact material due to its low resistivity, ability to form an ohmic connection, and compatibility with silicon. During the deposition of nickel on silicon, followed by annealing at elevated temperatures, the nickel reacts with the underlying silicon to form nickel silicide. The annealing of nickel silicide can result in various phases, such as, for example, nickel monosilicide (NiSi), dinickel silicide (Ni₂Si), nickel disilicide (NiSi₂), nickel trisilicide (NiSi₃), etc., (collectively, “nickel silicide”).

Nickel silicide films may be used, for example, to facilitate an electrical interconnection between a metallic contact and the silicon in a source/drain region or gate electrode of a field-effect transistor (FET), or a emitter, base or collector region of a bipolar junction transistor (BJT). For example, a nickel silicide film may be formed or “grown” at the interface where a metallic layer contacts polysilicon at the transistor gate, or where a metallic layer contacts monocrystalline silicon in the active area where the source and drain are located.

As described further below, the formation of nickel silicide at a contact surface generally involves a sequence of heating or annealing steps. In some examples, a semiconductor substrate is processed to at least partially form a semiconductor device, such as transistors or other circuitry. Multiple layers of nickel platinum (NiPt) are deposited onto the substrate, with varying atomic percentages of platinum in each layer. A first heating step can be performed at a lower temperature (e.g., around 240° C.-400° C.) to initiate the reaction between nickel and silicon that results in a diffusion of at least some of the deposited nickel into an underlying layer including silicon. The first heating step may form one or more phases of nickel-containing silicide (e.g., NiSi₂, NiPtSi₂, Ni₂Si, or Ni₂PtSi) near the contact surface, which may include unreacted platinum at certain grain boundaries. Optionally, a selective etching may be performed to remove any unreacted NiPt, sometimes referred to herein as an “overburden” of NiPt, that has not formed a silicide phase. The etching may help to ensure good contact formation and later connection of vertical interconnects (“contacts”) to the silicide layer. A second heating or annealing step can be performed at a higher temperature (e.g., 550-750° C.). The second heating step may enhance the formation of a lower resistivity phase of nickel platinum silicide (e.g., NiSi or NiPtSi), which may include unreacted platinum at certain grain boundaries. After the heating or annealing steps have been performed in sequence, the substrate may undergo further processing steps such as deposition of dielectric layers, patterning, and metallization to complete the fabrication of the semiconductor device.

The thermal annealing of nickel silicide risks giving rise to a variety of technical problems. For example, as stated above, thermal annealing of nickel silicide can create NiSi₂ at a contact surface. Nickel disilicide can form, for example, when nickel reacts with silicon at temperatures within the range of 350-600° C. Nickel disilicide has a monoclinic C54 crystal structure. While nickel disilicide is one of the most stable phases of nickel silicide at lower annealing temperatures, and has good electrical conductivity, it may not be the most suitable phase of nickel silicide for certain applications.

The formation of certain phases of nickel silicide (e.g., NiSi₂) at or near a contact surface can result in higher electrical resistance relative to other phases of nickel silicide, which can degrade performance or reliability of certain semiconductor devices. In addition, concentration of certain phases of nickel silicide (e.g., Ni₂Si) at or near a contact surface may increase the risk of forming nickel encroachment defects, which can extend from the contact surface in the shape of a spike or pipe and thereby cause an electrical short or other catastrophic failure and reliability issues. The thermal annealing of nickel silicide can also increase the risk of agglomeration, in which a nickel silicide film undergoes transformation from a uniform, continuous layer into separate islands or clusters of nickel silicide. Agglomeration can be undesirable in semiconductor processing because it can result in discontinuities or poor quality of the nickel silicide layer. These discontinuities can adversely affect the electrical properties of the contacts formed with nickel silicide, leading to increased contact resistance or device failure. Thus, when fabricating certain semiconductor devices, controlling the high-temperature thermal annealing of a nickel silicide film may facilitate the formation of a uniform, continuous, and low resistance layer proximate to a contact surface.

The introduction of platinum (Pt) to a nickel silicide film and the controlled annealing of platinum together with multiple layers of nickel silicide film has been shown to provide or contribute to several technical advantages. For example, the inclusion of platinum can restrict nickel diffusion and can cause smaller grains to form. In addition, platinum, when subjected to annealing, can interact with underlying dopants and potentially form binary compounds with the dopants, which can improve electrical conductivity. Adjusting the atomic percentage of platinum at a contact surface and underlying barrier can be used to fine-tune material properties in a manner that optimizes device performance. The introduction of platinum into nickel silicide films may have other potential benefits, such as, for example, reducing the formation of certain phases of nickel silicide having higher electrical resistivity (e.g., NiSi₂) during thermal annealing, reducing or even eliminating nickel encroachment defects that may be especially prevalent with the presence of certain nickel silicide phases (e.g., Ni₂Si), reducing agglomeration, and generally enhancing electrical conductivity at contact surfaces. In addition, as explained further below, certain examples achieve high thermal stability, increase oxidation resistance, and provide a variety of additional device improvements.

While the introduction of platinum to a nickel silicide film may provide certain technical advantages, the inclusion of too much platinum at a contact surface can itself introduce technical challenges. Because it may be necessary to remove any excess or unannealed platinum from the contact surface, the inclusion of too much platinum or too high a concentration of platinum near the contact surface may increase the difficultly in removing the any such excess or unannealed platinum.

Accordingly, certain examples deposit multiple layers of NiPt (e.g., a stack of two, three, four, or more NiPt layers), with each NiPt layer having a different Pt % concentration relative to the others. The formation of a multilayer stack of NiPt having varying Pt % concentration can be followed by multiple thermal annealing process steps. The annealing process steps may result in annealing certain phases of nickel silicide (e.g., Ni₂Si or NiSi₂) into other phases of nickel silicide that, when combined with platinum or another metal (e.g., NiPtSi), have more desirable electrical properties for certain applications. The example processing disclosed herein can be fine-tuned to accommodate a variety of different semiconductor devices, depending on whatever platinum concentration is deemed optimal for an annealed nickel platinum silicide film proximate to a contact surface. The deposition of multiple NiPt layers having different platinum atomic percentages can also facilitate experimental testing of Pt % concentration (e.g., for strip development and device targeting).

Various examples are described subsequently. Although the specific examples may illustrate various aspects of the above generally described features, examples may incorporate any combination of the above generally described features (which are described in more detail in examples below).

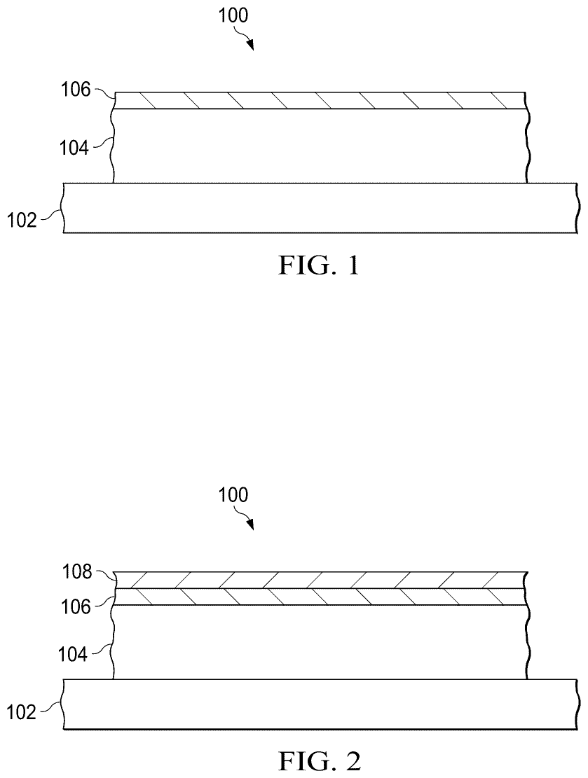

FIGS. 1 through 6 are respective cross-sectional views of a portion of a semiconductor device 100 in intermediate stages of manufacturing according to some examples. Referring to FIG. 1, a semiconductor substrate 102 is received in a processing chamber of a multi-chamber cluster tool. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer grown on the support substrate. In some examples, semiconductor substrate 102 is or includes a silicon substrate (which may be singulated from a bulk silicon wafer at the conclusion of semiconductor processing). In further examples, semiconductor substrate 102 includes a silicon substrate with an epitaxial silicon layer grown thereon. Semiconductor substrate 102 is or includes a semiconductor material in and/or on which devices, such as one or more transistors, are formed. In some examples, the semiconductor material is or includes silicon (Si), silicon germanium (SiGe), gallium arsenide (GaAs), gallium nitride (GaN), the like, or a combination thereof.

A semiconductor layer 104 layer has been formed on substrate 102 in an earlier process step. Semiconductor layer 104 may include, for example, silicon, polysilicon, a monocrystalline layer, or other semiconductor material, including combinations thereof.

A nickel-platinum (NiₓPt_{y}) layer 106 is formed on semiconductor layer 104. The atomic percentages (at %) x and y may satisfy the equation: x+y≥0.99. The atomic percentages x and y may also, or alternatively, be represented by the equation: y=1−x. In some examples, x≤0.8 and y≥0.2.

The formation of NiₓPt_{y} layer 106 may include a series of process steps. For example, substrate 102 may be subjected to a Siconi® (registered trademark of Applied Materials Incorporated) preclean process. The preclean process can be configured to clean the outward-facing surface of semiconductor layer 104, thereby removing all oxygen at the growing surface and any other material that may inhibit the desired, controlled growth of nickel silicide. The preclean process can be followed by a deposition of NiₓPt_{y} layer 106 using a first sputtering target having the appropriate atomic percentages of nickel and platinum. The deposition may be performed, for example, in a first chamber of a multi-chamber cluster tool and using physical vapor deposition (PVD), chemical vapor deposition (CVD), or any other suitable deposition technique.

FIG. 2 shows semiconductor device 100 after the formation of a nickel-platinum (NiₘPtₙ) layer 108 on NiₓPt_{y} layer 106. The atomic percentages m and n (of NiₘPtₙ layer 108) may satisfy the equation: m+n≥0.99. The atomic percentages m and n may also, or alternatively, be represented by the equation: n=1−m. In some examples, m≥0.9 and n≤0.1. In some examples, the platinum concentration in NiₓPt_{y} layer 106 layer is different from the platinum concentration in NiₘPtₙ layer 108. For example, the platinum concentration in NiₘPtₙ layer 108 can be less than the platinum concentration in NiₓPt_{y} layer 106, such that m>x and n<y. Alternatively, the platinum concentration in NiₘPtₙ layer 108 can be greater than the platinum concentration in NiₓPt_{y} layer 106, such that m<x and n>y.

The formation of NiₘPtₙ layer 108 may include a series of process steps. In some examples, NiₘPtₙ layer 108 is formed by a deposition using a second sputtering target having the appropriate atomic percentages of nickel and platinum. The deposition may be performed, for example, in a second chamber of the same multi-chamber cluster tool, where the second chamber is different from the first chamber, and where vacuum is not necessarily broken at any time between the respective formation of NiₓPt_{y} layer 106 and NiₘPtₙ layer 108. The deposition of NiₘPtₙ layer 108 may be performed using PVD, CVD, or any other suitable deposition technique.

Use of a multilayer NiPt stack (e.g., including layers 106 and 108), with a different atomic percentage of platinum for each layer thereof, may provide any of a variety of technical advantages. As explained further with reference to FIG. 4, for example, the removal of any overburden of NiPt may be facilitated by using a reduced platinum concentration at the exposed surface of the stack (e.g., at an exposed surface of NiₘPtₙ layer 108) relative to an interior thereof (e.g., within NiₓPt_{y} layer 106). The deposition of multiple NiPt layers having varying platinum atomic percentages can also facilitate experimental testing of Pt % concentration (e.g., for strip development and device targeting). When subjected to annealing, platinum can interact with underlying dopants and potentially form binaries with the dopants, which can improve electrical conductivity. Other possible technical advantages of using a multilayer NiPt stack having varying platinum concentrations for each layer include: reducing electrical resistance at a contact surface, increasing oxidation resistance, controlling the amount of nickel diffusion in nickel silicide films, reducing grain size in annealed nickel silicide films, reducing the formation of certain phases of nickel silicide (e.g., NiSi₂) deemed less favorable for certain applications, reducing or even eliminating nickel encroachment defects, reducing agglomeration, or any of the other technical advantages described herein.

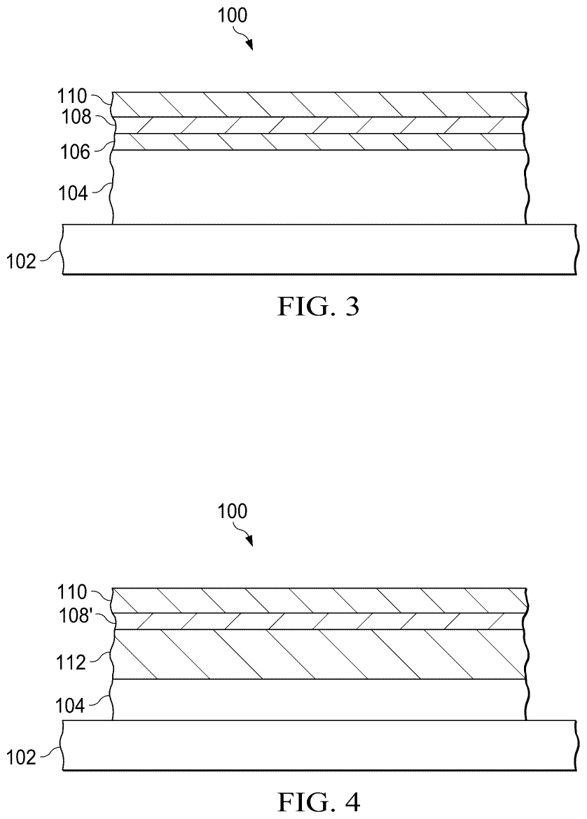

FIG. 3 shows semiconductor device 100 after the formation of an optional capping layer 110 on NiₘPtₙ layer 108. In some examples, capping layer 110 may include a material that inhibits oxidation of a nickel silicide film that could otherwise form during annealing processing that is performed after forming NiₘPtₙ layer 108. For example, capping layer 110 may include titanium nitride (TiN). However, any suitable material that helps prevent oxidation of nickel silicide may be used.

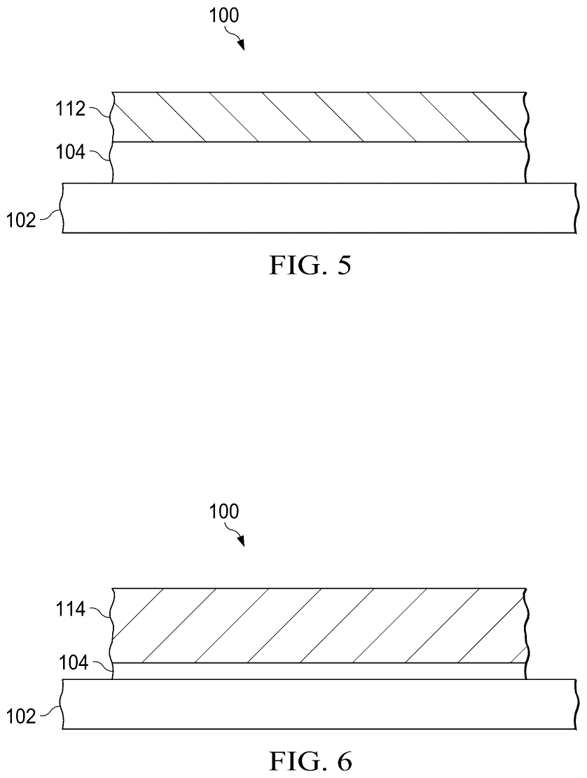

In some embodiments the total thickness of the NiPt stack (including NiₓPt_{y} layer 106 and NiₘPtₙ layer 108) may be sufficient to provide an overburden of NiPt that is not reacted with the semiconductor layer 104. As result of this overburden, a portion of the NiPt stack may remain unreacted or undiffused (e.g., layer 108′ described with reference to FIG. 4) after completion of one or more heating steps used in forming a nickel silicide film. A sufficiently thick layer of unreacted or undiffused NiPt at an upper surface may itself be sufficient to prevent oxidation of underlying nickel silicide, such that deposition and subsequent removal of a caping layer 110 can be omitted. The thickness of the NiPt stack may be optimized, for example, to allow for a targeted amount of overburden that is sufficient to prevent oxidation in the absence of a capping layer 110, while also facilitating the subsequent removal of all overburden material (as further described with reference to FIG. 5).

FIG. 4 shows semiconductor device 100 after the completion of one or more heating steps, which cause an annealing reaction involving semiconductor layer 104, a least a portion of NiₓPt_{y} layer 106, and possibly a portion of NiₘPtₙ layer 108, thereby forming an annealed layer 112 including Ni₂Si and platinum. The heating and the resultant annealing reaction consumes or diffuses at least a portion (or all) of NiₓPt_{y} layer 106 and at least a portion of NiₘPtₙ layer 108 into the annealed layer 112. In some examples, the consumed or diffused portion of NiₘPtₙ layer 108 may amount to approximately 60%-70% (e.g., ⅔) of the total cumulative thickness of the NiPt stack (including NiₓPt_{y} layer 106 and NiₘPtₙ layer 108). The amount of NiₓPt_{y} layer 106 diffused into annealed layer 112 may be varied, for example, by varying the time and temperature of the heating step(s). Any suitable temperature and timing can be used. The heating step(s) may involve, for example, exposing substrate 102 (and all layers formed thereon) to an annealing temperature within the inclusive range of 240° C.-400° C. A “spike” heating process can be used, in which the temperature is rapidly ramped up to a peak temperature and then rapidly ramped down to a cooler temperature. Alternatively, a “soak” process can be used, in which a target temperature is maintained for a fixed time (e.g., within the range of 10 seconds to 330 seconds).

Annealed layer 112 can extend into at least a portion of the thickness of the semiconductor layer 104 shown in FIGS. 1 through 3. In other words, the completion of one or more heating steps results in consuming a portion of semiconductor layer 104 into annealed layer 112, thereby reducing the thickness of semiconductor layer 104.

Layer 108′ is referred to herein as the “overburden” material because layer 108′ represents a remaining portion of NiₘPtₙ layer 108 that is unreacted or undiffused. The overburden layer 108′ may have a reduced thickness relative to the NiₘPtₙ layer 108 shown in FIGS. 2 and 3. The relative reduced thickness of overburden layer 108′ may be the result of NiₘPtₙ layer 108 reacting with one or more underlying layers during one or more thermal annealing processes.

FIG. 5 shows semiconductor device 100 after removal of layers 108′ and 110, thereby exposing an upper surface of layer 112. In some examples, capping layer 110 is formed on NiₘPtₙ layer 108 before the heating described above (that forms the annealed layer 112) and the capping layer 110 is removed (together with overburden layer 108′) after the heating. Semiconductor device 100 may have certain areas where layers 106 and 108 do not overlay silicon and hence did not diffuse into an underlying layer during the heating/annealing processing described above. In addition, there may be an overburden of layers 106 and 108 such that a portion of either layer (e.g., overburden layer 108′) remains unreacted/undiffused. Under either scenario, it may be beneficial, or even necessary, to remove the unreacted or undiffused portions of layers 106 and 108 (if any). The removal of unreacted or undiffused portions of layers 106 and 108 may remove the risk of electrical shorting that may otherwise occur.

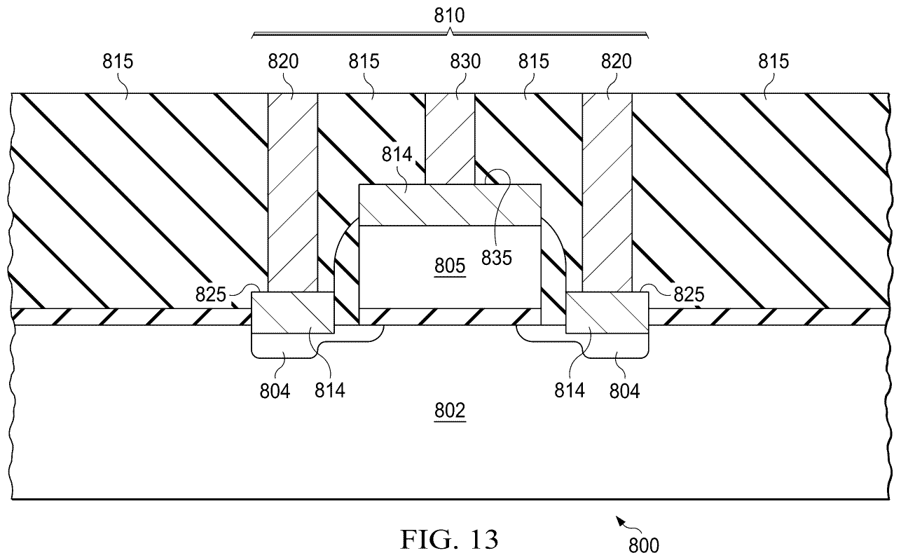

FIG. 6 shows semiconductor device 100 after the completion of one or more heating steps, which cause an annealing reaction involving annealed layer 112 (including Ni₂Si and platinum) and semiconductor layer 104, thereby forming an annealed layer 114 having NiPtSi and platinum. More specifically, the heating step(s) used to form annealed layer 114 can cause a greater percentage of nickel in annealed layer 112 to diffuse into the underlying semiconductor layer 104, resulting in converting the 2:1 atomic ratio of nickel to silicon (within annealed layer 112) to a 1:1 atomic ratio of nickel to silicon (within annealed layer 114). The 1:1 atomic ratio of nickel to silicon in annealed layer 114 lowers electrical resistance and may improve conditions of an upper contact surface prepared to receive the deposition of one or more metallic layers (e.g., as shown in FIG. 13).

In some examples, the formation of annealed layer 114 involves one or more controlled heating steps involving any suitable temperature and timing. The heating step(s) may involve, for example, exposing substrate 102 (and all layers formed thereon) to an annealing temperature within the inclusive range of 500° C.-600° C. In some examples, a “spike” or “soak” heating process is used, with the latter involving maintaining a target temperature for a fixed time (e.g., within the range of 10 seconds to 330 seconds). Some examples may involve a laser anneal optionally applied for a shorter duration of time (e.g., milliseconds) and at elevated temperature(s) within the range of 750° C.-950° C.

Annealed layer 114 can extend into at least a portion of the thickness of the semiconductor layer 104 shown in FIGS. 1 through 3. Annealed layer 114 may have thickness greater than annealed layer 112 shown in FIGS. 4 and 5. In some examples, annealed layer 114 has a thickness greater than 30 nanometers, or within the range of 10 to 35 nanometers. However, annealed layer 114 may be grown to any suitable thickness.

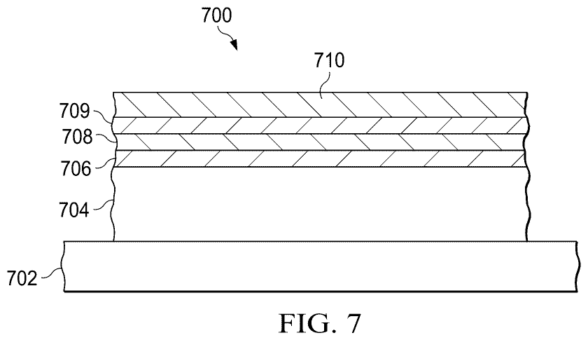

The foregoing principles may be extended to use more than two N—Pt alloy layers in forming a silicide layer. FIG. 7 is a cross-sectional view of a portion of a semiconductor device 700 at an intermediate stage of manufacturing according to some examples. In this example, a material stack includes: a semiconductor layer 704 on a substrate 702, a nickel-platinum (Ni_{x′}Pt_{y′}) layer 706 on semiconductor 704, a nickel-platinum (Ni_{n′}Pt_{m′}) layer 708 on Ni_{x′}Pt_{y′} layer 706, a nickel-platinum (Ni_{p′}Pt_{q′}) layer 709 on Ni_{x′}Pt_{y′} layer 708, and an optional capping layer 710 on Ni_{p′}Pt_{q′} layer 709. Substrate 702 may be substantially similar to substrate 102 of FIGS. 1 through 6. Semiconductor layer 704 may be substantially similar to semiconductor layer 104 of FIGS. 1 through 6. Capping layer 710 may be substantially similar to capping layer 110 of FIGS. 3 and 4.

The formation of NiPt layers 706-709 may include a series of process steps. For example, substrate 102 may be subjected to a Siconi® preclean process, followed by deposition of Ni_{x′}Pt_{y′} layer 706 (e.g., using PVD or CVD techniques) on semiconductor layer 704. The deposition used to form Ni_{x′}Pt_{y′} layer 706 may be performed, for example, in a first chamber of a multi-chamber cluster tool using a first sputtering target having the appropriate atomic percentages of nickel and platinum (x′ and y′ respectively). Ni_{m′}Pt_{n′} layer 708 may be deposited (e.g., using PVD or CVD techniques) on Ni_{x′}Pt_{y′} layer 706. The deposition of Ni_{m′}Pt_{n′} layer 708 may be performed in a second chamber (of the same multi-chamber cluster tool) using a second sputtering target configured to accommodate the appropriate atomic percentages of nickel and platinum (m′ and n′, respectively). Ni_{p′}Pt_{q′} layer 710 may be deposited (e.g., using PVD or CVD techniques) on Ni_{m′}Pt_{n′} layer 708. The deposition of Ni_{p′}Pt_{q′} layer 710 may be performed in a third chamber (of the same multi-chamber cluster tool) using a third sputtering target configured to accommodate the appropriate atomic percentages of nickel and platinum (p′ and q′, respectively).

Ni—Pt layers 706-709 may be formed with each having a different atomic percentage of Pt relative to the other layers. For example, the atomic percentages y′, n′, and q′ may satisfy the relationships y′>n′>q′. In some examples, y′≥0.2, 0.1<n′≤0.15, q′≤0.1.

After layers 706-710 are formed, one or more heating steps are performed that cause an annealing reaction involving source/drain regions 804, at least a portion of Ni_{x′}Pt_{y′} layer 706, a portion of Ni_{m′}Pt_{n′} layer 708, and Ni_{p′}Pt_{q′} layer 709, thereby forming an annealed layer including Ni₂Si and platinum. The heating step(s) may be similar to that described above with reference to FIG. 4, wherein the heating and the resultant annealing reaction consumes or diffuses at least a portion (or all) of layers 706-709 into the annealed layer. In some examples, the consumed or diffused portion of layers 706-709 may amount to approximately 60%-70% (e.g., ⅔) of the total cumulative thickness of the NiPt stack including layers 706-709. The amount of layers 706, 708, or 709 that is diffused may be varied, for example, by varying the time and temperature of the heating step(s). Any suitable temperature and timing can be used.

After heating layers 706-709 to form an annealed layer including Ni₂Si and platinum, one or more subsequent heating steps may be are performed that cause an annealing reaction involving the annealed Ni₂Si and platinum and source/drain regions 804, thereby forming an annealed silicide layer having NiPtSi and platinum. The heating step(s) may be similar to that described above with reference to FIG. 6, wherein a greater percentage of nickel is diffused into the underlying source/drain regions 804, resulting in converting the 2:1 atomic ratio of nickel to silicon to a 1:1 atomic ratio of nickel to silicon in at least a portion of the silicide layer. The 1:1 atomic ratio of nickel to silicon lowers electrical resistance and may improve conditions of an upper contact surface prepared to receive the deposition of one or more metallic layers (e.g., as shown in FIG. 13).

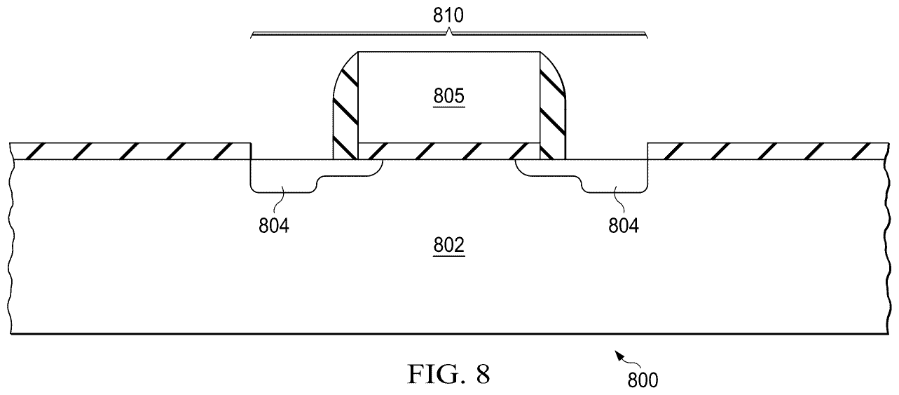

Although FIG. 1 through 6 and FIG. 7 each show a respective example stack of material in simplified block form to facilitate the description, in implementation one or more of the illustrated layers 102-114 of FIG. 1 through 6, or one or more of the illustrated layers 704-710 of FIG. 7, may conform to a respective underlying layer in a manner that creates various surfaces that are not coplanar or parallel to one another. An example of such varying surface features is described further with reference to FIGS. 8 through 13.

FIGS. 8 through 13 are respective cross-sectional views showing portions of a partially-formed semiconductor device 800, including a transistor region 810, in which are shown intermediate stages of manufacturing according to some examples. These figures are described in the context of a FET as one example. The described principles may be applied to other semiconductor devices, for example without limitation, BJTs.

Referring to FIG. 8, transistor region 810 includes substrate 802 having source/drain regions 804 and a gate electrode 805 formed thereover. The source/drain regions 804 and gate electrode 805 are terminals of the semiconductor device 800. The source/drain regions are typically monocrystalline, and the gate electrode 805 may be polycrystalline. The transistor region 810 includes unreferenced gate sidewall spacers and a gate dielectric layer between the gate electrode 805 and the substrate 802. An unreferenced dielectric layer, e.g. a silicon nitride layer, outside the transistor region 810 may serve as a silicide blocking layer.

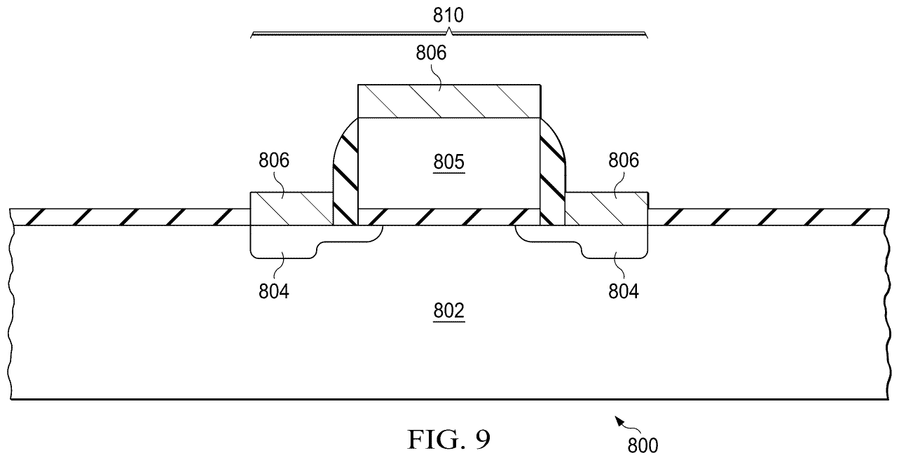

FIG. 9 shows the transistor region 810 of semiconductor device 800 after the formation of NiₓPt_{y} layers 806 on source/drain regions 804 and gate electrode 805, analogous to the description with reference to FIG. 1.

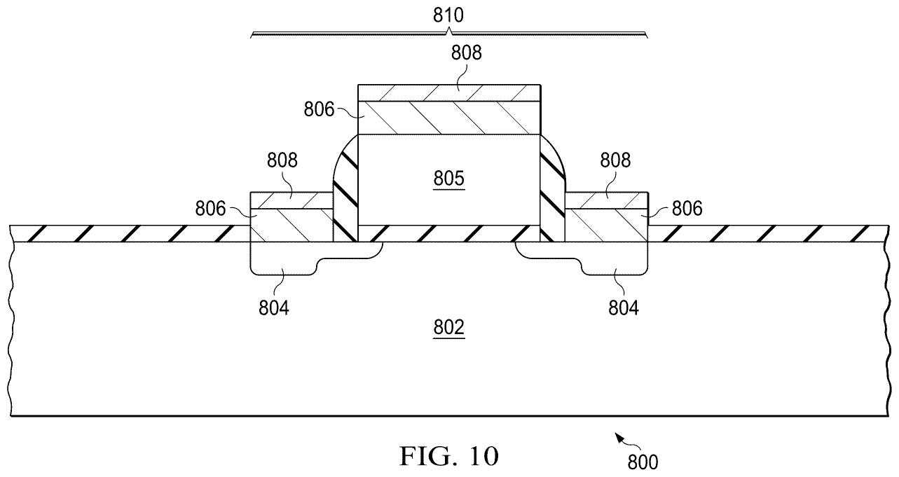

FIG. 10 shows the transistor region 810 of semiconductor device 800 after the formation of NiₘPtₙ layers 808 on NiₓPt_{y} layers 806, analogous to the description with reference to FIG. 2.

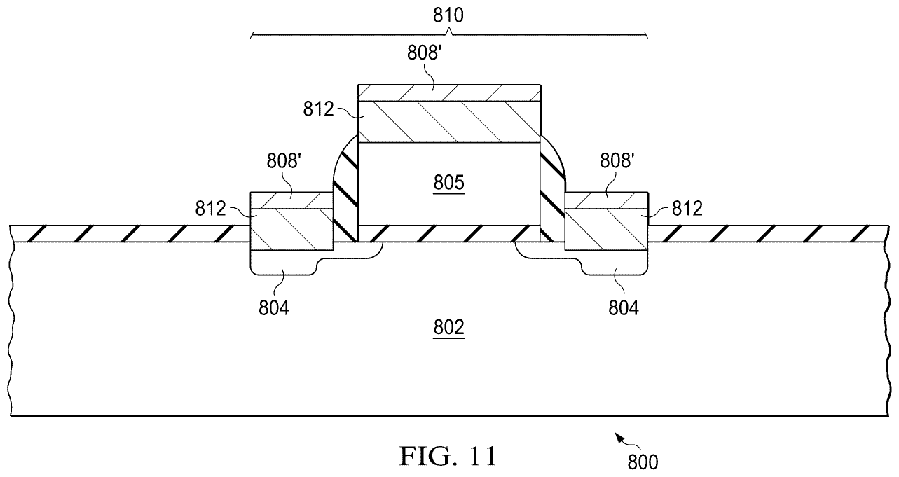

FIG. 11 shows the transistor region 810 of semiconductor device 800 after one or more heating steps that causes a reaction involving respective portions of the source/drain regions 804 and gate electrode 805 with Ni—Pt layer 806 and 808, thereby forming annealed layers 812 having Ni₂Si and platinum, as described further above with reference to FIG. 4. Overburden layer 808′ represents a remaining unreacted portion of NiₘPtₙ layer 808.

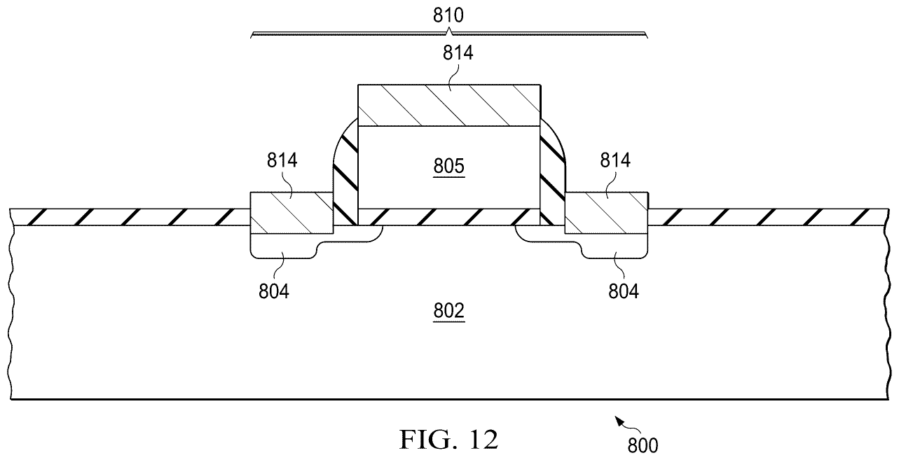

FIG. 12 shows the transistor region 810 of semiconductor device 800 after one or more heating steps that cause a reaction involving annealed layers 812, thereby forming annealed layers 814 having nickel, platinum and silicon, e.g. including binary and ternary compounds thereof such as NiSi, PtSi and NiPtSi.

FIG. 13 shows the transistor region 810 of semiconductor device 800 after the formation of a dielectric layer 815 and vertical interconnects, or contacts, 820 and 830. Contacts 820 connect to upper surfaces 825 of annealed layers 814 over the source/drain regions 804. Contact 830 contacts an upper surface 835 of annealed layer 814 over the gate electrode 805. Because respective portions of annealed layers 814 are in direct contact with contacts 820 and 830, annealed layers 814 may be deemed “contact layers” for purposes of this disclosure. The formation of annealed layers 814 having NiPtSi and platinum proximate upper surfaces 825 and 835 can provide or contribute to several technical advantages described herein, such as, for example, reducing the formation of certain undesired phases of nickel silicide (e.g., NiSi₂, Ni₂Si) near a contact surface, reducing or eliminating nickel encroachment defects, reducing agglomeration, and reducing electrical resistance. In addition, certain examples achieve high thermal stability, increase oxidation resistance, and provide a variety of additional device improvements.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. To aid the Patent Office, and any readers of any patent issued on this application, in interpreting the claims appended hereto, applicant notes that there is no intention that any of the appended claims invoke 35 U.S.C. § 112(f) as it exists on the date of filing hereof unless the words “means for” or “step for” are explicitly used in the claim language.

In the foregoing descriptions, for purposes of explanation, numerous specific details are set forth to provide a thorough understanding of one or more examples. However, this disclosure may be practiced without some or all these specific details, as will be evident to one having ordinary skill in the art. In other instances, well-known process steps or structures have not been described in detail in order not to unnecessarily obscure this disclosure. In addition, the foregoing description is not intended to limit the disclosure to the described examples. To the contrary, the description is intended to cover alterations, modifications, substitutions, and equivalents as may be included without departing from the scope defined by the appended claims.

What is claimed is:

1. A method of forming an integrated circuit, comprising:
receiving a partially formed semiconductor device over a substrate, the semiconductor device including a semiconductor layer
forming a NiₓPt_{y} layer on a top surface of the semiconductor layer;
forming a NiₘPtₙ layer on the NiₓPt_{y} layer, n<y;
heating the NiₓPt_{y} layer and the NiₘPtₙ layer, thereby forming a nickel silicide layer extending into the semiconductor layer; and
removing a remaining portion of the NiₘPtₙ layer.

2. The method of claim 1, wherein the heating consumes a portion of the NiₘPtₙ layer into the nickel silicide layer.

3. The method of claim 2, further comprising forming a TiN layer over the NiₓPt_{y} layer before the heating and removing the TiN layer after the heating.

4. The method of claim 1, wherein y≥0.2 and n≤0.1.

5. The method of claim 1, wherein x+y≥0.99 and m+n≥0.99.

6. The method of claim 1, wherein the semiconductor layer includes polysilicon at the top surface.

7. The method of claim 1, wherein the semiconductor layer includes a monocrystalline layer at the top surface.

8. The method of claim 1, further comprising heating the nickel silicide layer after removing the NiₘPtₙ layer, thereby forming a layer including nickel, platinum and silicon extending into the semiconductor layer.

9. The method of claim 8, wherein the layer including nickel platinum silicide has a thickness within the inclusive range of 10 to 35 nanometers.

10. The method of claim 1, further comprising forming a NiₚPt_{q} layer on the NiₘPtₙ layer, wherein 0.1<n≤0.15, and q≤0.1.

11. The method of claim 1, wherein the nickel silicide layer is located on a transistor terminal.

12. The method of claim 1, wherein the NiₓPt_{y} layer is formed in a first process chamber with a first sputtering target with a first Pt concentration, and the NiₘPtₙ layer is formed in a second process chamber with a second sputtering target with a different second Pt concentration.

13. A method of forming an integrated circuit, comprising:
forming a NiₓPt_{y} layer on a semiconductor layer over a substrate;
forming a NiₘPtₙ layer on the NiₓPt_{y} layer, y>n;
forming a NiₚPt_{q} layer on the NiₘPtₙ layer, n>q;
heating the NiₓPt_{y} layer, the NiₘPtₙ layer, and the NiₚPt_{q} layer, thereby forming a silicide layer including nickel, silicon and platinum on the semiconductor layer; and
removing a remaining portion of the NiₚPt_{q} layer.

14. The method of claim 13, wherein the heating consumes portions of the NiₓPt_{y} and NiₘPtₙ layers into the silicide layer.

15. The method of claim 13, further comprising forming a TiN layer on the NiₚPt_{q} layer before the heating, and removing the TiN layer after the heating.

16. The method of claim 13, wherein y≥0.2, 0.2<n<0.15 and q≤0.15.

17. The method of claim 13, wherein the semiconductor layer comprises polysilicon.

18. The method of claim 13, wherein the semiconductor layer includes a monocrystalline layer.

19. The method of claim 13, further comprising heating the silicide layer after removing the NiₚPt_{q} layer, thereby forming a nickel platinum silicide layer.

20. A method of forming an integrated circuit, comprising:
receiving a partially formed semiconductor device over a substrate, the semiconductor device including a semiconductor layer
forming a NiₓPt_{y} layer on the semiconductor layer;
forming a NiₘPtₙ layer on the NiₓPt_{y} layer, n<y; and
forming a contact layer having nickel platinum silicide (NiPtSi) by reacting the NiₓPt_{y} layer with the semiconductor layer.

21. The method of claim 20, wherein forming the contact layer includes reacting the NiₘPtₙ layer with the semiconductor layer.

22. The method of claim 20, further comprising forming a NiₚPt_{q} layer on the NiₘPtₙ layer, q<n, before forming the contact layer.
